(19) United States
(12) Patent Application Publication
(10) Pub. No.: US 2025/0029954 A1
(43) Pub. Date: Jan. 23, 2025

(54) SEMICONDUCTOR DEVICES AND MANUFACTURING METHODS THEREOF, CHIP PACKAGE STRUCTURES

(71) Applicant: Yangtze Memory Technologies Co., Ltd., Wuhan (CN)

(72) Inventors: Min Wen, Wuhan (CN); Yingcheng Zhao, Wuhan (CN); Bo Wang, Wuhan (CN); Chengbao Zhou, Wuhan (CN); Zhen Pan, Wuhan (CN); Mingkang Zhang, Wuhan (CN); Shu Wu, Wuhan (CN)

(21) Appl. No.: 18/528,301

(22) Filed: Dec. 4, 2023

(30) Foreign Application Priority Data
Jul. 20, 2023 (CN) 202310906048.8

(51) Int. Cl. H01L 25/065; H01L 21/56; H01L 23/00; H01L 23/31; H01L 23/538; H01L 25/00

(52) U.S. Cl. CPC H01L 25/0657; H01L 21/568; H01L 23/3107; H01L 23/5386; H01L 24/16; H01L 25/50; H01L 2224/16227

(57) ABSTRACT

In one example, a semiconductor device includes a conductive layer, composite structures, conductive posts and first pads. The composite structures may be located on the conductive layer and stacked in a direction perpendicular to the plane in which the conductive layer is located. The composite structure may include a chip, an insulating layer surrounding around the chip, and at least one second pad electrically connected with the chip. The second pad is located on the insulating layer. The second pads of the composite structures are at different locations in the first direction. The first direction is perpendicular to the thickness direction of the composite structures. The conductive posts are located in the insulating layer of the composite structures and each conductive post is connected with one of the second pads and one of the first pads.

### REFERENCE TO RELATED APPLICATIONS

This application claims priority to and the benefit of Chinese Patent Application 202310906048.8, filed on Jul. 20, 2023, which is hereby incorporated by reference in its entirety.

### TECHNICAL FIELD

The present disclosure relates to the field of semiconductor technology, and particularly to semiconductor devices and manufacturing methods thereof, as well as a chip package structures.

### BACKGROUND

At present, as the technology has matured in the semiconductor industry, the miniaturization of chip package structures has become a trend. Since the feature sizes of chips inside the chip package structures approach their lower limit, higher and higher requirements have been proposed on the chip package technology in order to realize miniaturization of the chip package structure.

### BRIEF DESCRIPTION OF DRAWINGS

In order to explain the technical solutions in the present disclosure more clearly, accompanying drawings required in some examples of the present disclosure will be described in brief below. The below described drawings are only drawings of some examples of the present disclosure and other drawings may be obtained according to these drawings for those of ordinary skill in the art. Furthermore, accompanying drawings described below may be regarded as illustrative diagrams rather than limiting the practical sizes of products, and practical flows of methods involved in examples of the present disclosure.

FIG. 1 is a diagram of a chip package structure according to some examples of the present disclosure;

FIG. 2 is a structure diagram of a semiconductor device according to some examples of the present disclosure;

FIG. 3A is a structure diagram of another semiconductor device according to some examples of the present disclosure;

FIG. 3B is a structure diagram of yet another semiconductor device according to some examples of the present disclosure;

FIG. 4 is a structure diagram of yet another semiconductor device according to some examples of the present disclosure;

FIG. 5 is a structure diagram of a chip package structure according to some examples of the present disclosure;

FIG. 6 is a flowchart of a manufacturing method of a semiconductor device according to some examples of the present disclosure;

FIGS. 7-10 are structure diagrams corresponding a manufacturing method of a semiconductor device according to some examples of the present disclosure;

FIGS. 11-16 are diagrams of a manufacturing method of another semiconductor device according to some examples of the present disclosure;

FIGS. 17-20 are structure diagrams corresponding a manufacturing method of yet another semiconductor device according to some examples of the present disclosure; and

FIG. 21 is structure diagrams corresponding a manufacturing method of yet another semiconductor device according to some examples of the present disclosure.

### DETAILED DESCRIPTION

The technical solution in examples of the present disclosure will be described below clearly and completely with reference to accompanying drawings. However, the described examples are only partial examples rather than all examples of the present disclosure. All other examples obtained by one of ordinary skill in the art based on examples provided in the present disclosure fall within the scope of the present disclosure.

In the description of the present disclosure, it is to be understood that terms “middle”, “on”, “under”, “front”, “rear”, “left”, “right”, “horizontal”, “inner” etc. refer to the azimuth or position relationship based on what is shown in figures, which are only for the purpose of facilitating describing the present disclosure and simplifying description rather than indicating or implying that the mentioned devices or elements must have certain azimuth, must be constructed and operated in certain azimuth, and therefore are not constructed as limiting the present disclosure.

Unless otherwise stated in context, the term “include” will be interpreted in an open and containing sense, namely “contain but not limited to” throughout the description and claims. In the description of the specification, terms such as “one example,” “some examples,” “illustrative example,” “illustratively” or “some examples” are intended to indicate particular features, structures, materials or characteristics related to the implementation(s) or example(s) are included in at least one implementation or example of the present disclosure. The illustrative representation of the above terms does not necessarily refer to the same implementation or example. Furthermore, said particular features, structures, materials or characteristics may be included in any one or more implementations or examples in any suitable manner.

Hereinbelow, the terms “first,” “second” etc. are only used for the purpose of description and should not be understood to indicate or imply relative importance or to designate the number of the referenced technical features implicitly. Therefore, a feature qualified by “first” or “second” may include one or more instances of the feature explicitly or implicitly. In the description of examples of the present disclosure, “a plurality of” means two or more unless otherwise specified.

While describing some examples, expressions such as “couple” and “connect” as well as derivatives thereof might be used. For example, the term “connect” may be used while describing some examples to indicate that two or more components have direct physical contact or electrical contact. As another example, the term “couple” may be used while describing some examples to indicate that two or more components have direct physical contact or electrical contact. However, the term “couple” may also indicate there is no direct contact between two or more components, but they still cooperate or interact with each other. Examples described herein are not necessarily limited to the contents provided herein.

Example implementations are described herein with reference to sectional views and/or plan views as ideal illustrative drawings. In the drawings, thicknesses of layers and areas of regions are enlarged for clarity. Therefore, it is possible to envision shape variations with respect to drawings due to manufacturing techniques and/or tolerances. Accordingly, example implementations should not be interpreted as limiting the shapes of regions shown herein, but including shape deviations caused by, for example, manufacturing. For example, an etched region shown as rectangular generally has curved features. Therefore, regions shown in drawings are illustrative in nature, and their shapes are not intended to show actual shapes of regions of a device and not intended to limit the scope of example implementations.

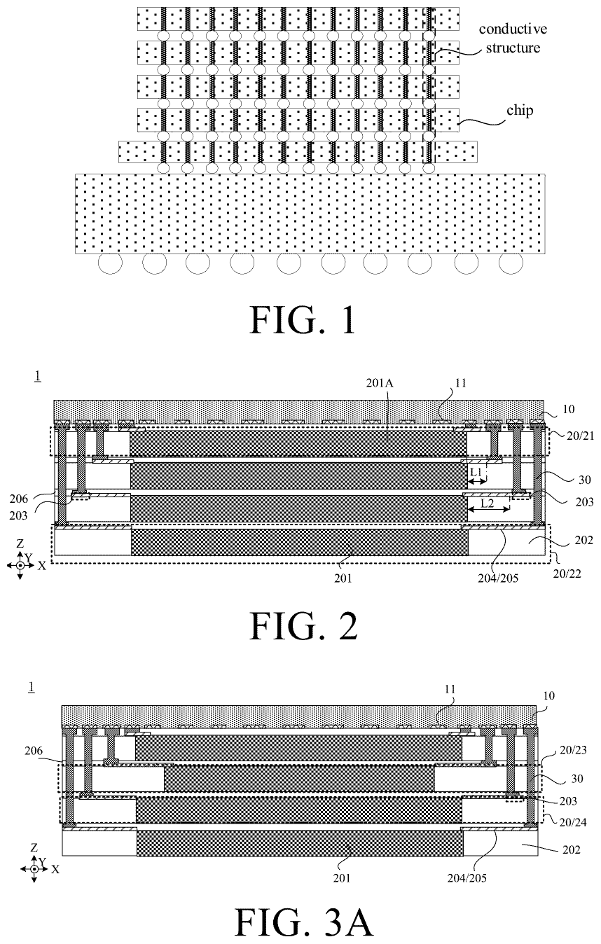

In an example, in a chip package structure as shown in FIG. 1, the conductive structures penetrating inside chips are provided among a plurality of chips. The conductive structures are formed by a through silicon via (TSV) process. The conductive structures will occupy spaces inside chips such that volumes of chips increase, which is unfavorable for miniaturization design and high integration design of chip package structures, and the conductive structures have high manufacturing cost and manufacturing difficulty.

As shown in FIG. 2, some examples of the present disclosure further provide a semiconductor device 1 including a conductive layer 10, a plurality of composite structures 20 and a plurality of conductive posts 30.

Illustratively, the conductive layer 10 includes a plurality of first pads 11. The plurality of composite structures 20 are located on the conductive layer 10 and stacked in a direction perpendicular to the plane in which the conductive layer 10 is located. The conductive layer 10 may be a redistribution layer (RDL) or conductive layer.

As shown in FIG. 2, the direction perpendicular to the plane in which the conductive layer 10 is located is the third direction Z shown in FIG. 2, and the thickness direction of the composite structure 20 is also the third direction Z in FIG. 2.

The composite structure 20 of the example includes: a chip 201, an insulating layer 202 surrounding around the chip 201, and at least one second pad 203 electrically connected with the chip 201. The second pad 203 is located on the insulating layer 202.

For example, the chip 201 is electrically connected with one of the second pads 203 or the chip 201 is electrically connected with a plurality of second pads 203.

For example, the chip 201 may be a DRAM (Dynamic Random Access Memory), a CIS (Complementary Metal-Oxide-Semiconductor Transistor Image Sensor), a HMC (Hybrid Memory Cube) etc.

Illustratively, chips 201 in different composite structures 20 may have the same function, such as storage function. Chips 201 in different composite structures 20 may also have different functions. For example, chips 201 in some composite structures 20 may have the function of the controller, chips 201 in other composite structures 20 may have the storage function, etc. Therefore, it is possible to control the storage process of other chips with the chips with the function of controller.

The plurality of second pads 203 are located around the chip 201. In some examples, as shown in FIG. 2, considering the first direction X as an example, the second pads 203 in the plurality of composite structures 20 are at different locations in the first direction X. The first direction X is perpendicular to the thickness direction Z of the composite structures 20. For example, the first direction X may be the horizontal direction in FIG. 2, and the first direction X is parallel to the plane in which the composite structure 20 is located. In the first direction X, locations of any two second pads 203 in different composite structures 20 do not coincide.

Illustratively, in the first direction X, orthogonal projections of the second pads 203 on the plane in which the conductive layer 10 is located at least partly do not overlap.

For example, in the orthogonal projections onto the conductive layer 10, the second pads 203 in respective composite structure 20 have non-overlapping portions with second pads 203 in other composite structures 20.

As another example, in the orthogonal projections onto the conductive layer 10, there are no overlapping portions between the second pads 203 in respective composite structure 20 and the second pads 203 in other composite structures 20. The second pads 203 in all composite structures 20 are disposed in offset manner.

In a composite structure 20, since the insulating layer 202 surrounds the chip 201, the second pads 203 disposed on the insulating layer 202 and the chip 201 electrically connected therewith are offset in the thickness direction of the composite structure 20.

In some examples, the plurality of conductive posts 30 are located in the insulating layer 202 of at least one of the composite structures 20 and each conductive post 30 is connected with one of the seconds pad 203 and one of the first pads 11.

The conductive posts 30 penetrate through the insulating layer 202 of at least one of the composite structures 20 and are electrically connected with the respective second pad 203. The conductive posts 30 are located aside the chip 201 electrically connected with the respective second pad 203 and has a certain spacing with the chip 201 in the first direction X.

It is understood that conductive posts 30 electrically connected with the second pads 203 in different composite structures 20 have different heights (the height herein refers to the size of a conductive post 30 in its extending direction, namely the distance between the end surface of the conductive post 30 that is connected with the first pad 11 and the end surface of the conductive post 30 that is connected with the second pad 203). Conductive posts 30 electrically connected with the second pads 203 in the same composite structure 20 have the same height since they pass through the insulating layer 202 with the same thickness.

In the semiconductor device 1 provided in the above-described example of the present disclosure, the second pads 203 in the composite structures 20 are disposed on the insulating layers 202 around the chips 201 and electrically connected with the respective chip 201, the second pads 203 of the plurality of composite structures 20 are at different locations in the first direction X, a plurality of conductive posts 30 located in the insulating layer 202 of the respective composite structure 20 are configured to implement electrical connections between the first pads 11 in the conductive layer 10 and the second pads 203 in the respective composite structure 20. Since the conductive posts 30 are located in the insulating layer 202 and the second pads 203 are located on the insulating layer 202 such that the integration of the composite structures 20 is not limited by the area of chips 201 in the composite structures 20. Therefore, a larger number of composite structures 20 may be integrated in the semiconductor device 1 such that the semiconductor device 1 has a higher integration, the integration of composite structures 20 is simpler and more convenient, and the combination types of the plurality of composite structures 20 in the semiconductor device 1 are more flexibly, thereby broadening the application scenario of the semiconductor device 1 significantly. The semiconductor device 1 provided in examples of the present disclosure may avoid the manufacturing process and integration method of drilling holes inside chips 201 to implement the plurality of composite structures 20, needs not to occupy spaces and areas inside the chips 201, thereby reducing the manufacturing process difficulty of the semiconductor device 1 and saving the manufacturing cost of the semiconductor device 1.

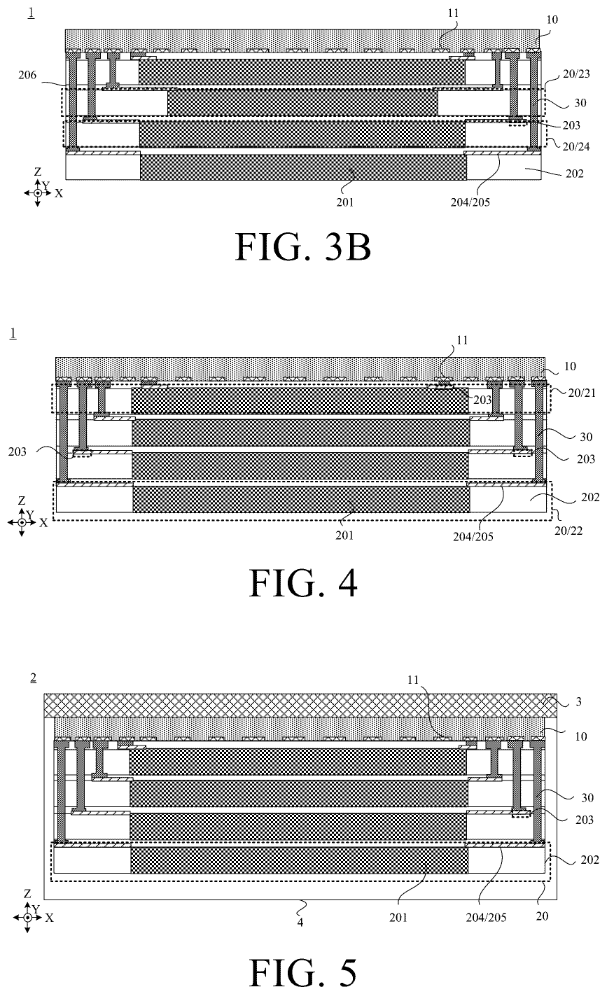

In some examples, as shown in FIGS. 2 and 3A, the conductive posts 30 extend in a direction perpendicular to the plane in which the conductive layer 10 is located and the plurality of conductive posts 30 are disposed parallel to each other. As a result, the plurality of conductive posts 30 can be arranged more regularly and the plurality of conductive posts 30 can be manufactured more conveniently.

The conductive posts 30 have various shapes and various sizes, which may be selected depending on practical conditions and are not limited in the present disclosure.

In some examples, the shape of the conductive posts 30 may be a cylinder or approximate cylinder. The range of the bottom surface diameter of the cylinder is 2 μm-50 μm. For example, the bottom surface diameter of the cylinder is 2 μm, 15 μm, 26 μm, 40 μm or 50 μm.

In some other examples, the shape of the conductive posts 30 may be a prism, such as a quadrangular prism. The quadrangular prism may be a straight quadrangular prism. A straight quadrangular prism refers to a quadrangular prism of which side edges are perpendicular to its bottom surface, and therefore also perpendicular to the plane in which the composite structure 20 is located. The minimum distance between any two side edges of the quadrangular prism is in a range of 2 μm-50 μm. For example, the minimum distance between any two side edges of the quadrangular prism is 2 μm, 19 μm, 31 μm, 40 μm or 50 μm.

For example, the quadrangular prism may be a cuboid.

It is appreciated that the shape of the conductive posts 30 is a cylinder in non-strict sense and a straight quadrangular prism in non-strict sense due to the manufacturing process errors and process limitations.

In some examples, in the at least one of the composite structures 20 as shown in FIGS. 2 and 3A, the number of the second pads 203 that are electrically connected with the same chip 201 is plurality.

For example, in the plurality of composite structures 20, the number of second pads 203 in respective composite structure 20 may be the same or different.

In some examples, in the at least one of the composite structures 20, the distances between the chip 201 and the plurality of second pads 203 electrically connected therewith are equal.

The “distance” may be the minimum distance.

For example, in each composite structure 20, the minimum distances between the chip 201 and the plurality of second pads 203 electrically connected therewith are all equal. Therefore, it is possible to realize uniform arrangement of the plurality of second pads 203, thereby reducing the design difficulty of the semiconductor device 1 and facilitating simplifying the manufacturing flow of the semiconductor device 1.

As another example, in the plurality of composite structures 20, the minimum distances between the chip 201 and the plurality of second pads 203 electrically connected therewith in one of the composite structures 20 are all equal, and the minimum distances between the chip 201 and the plurality of second pads 203 electrically connected therewith in another composite structure 20 are not equal. Therefore, it is possible to realize flexible arrangement of the second pads 203.

It is appreciated that in the same composite structure, there may be a plurality of disposing manners for relative positions between the plurality of second pads 203 and the chip 201, which may be selected depending on practical conditions and is not limited in the present disclosure.

In some examples, as shown in FIGS. 2 and 3A, in the at least one of the composite structures 20, the plurality of second pads 203 are located on at least two sides of the chip 201 electrically connected therewith.

For example, the number of the second pads 203 electrically connected with one of the chips 201 is two and the two pads are located on two opposite sides of the chip 201 in the first direction X.

With the setting, it is possible to make the distribution of the second pads 203 electrically connected with the same chip 201 disperse, with large spacing between two adjacent second pads 203, thereby reducing the risk of short-circuit due to small spacing between two adjacent second pads 203.

As another example, in the at least one of the composite structures 20, the plurality of second pads 203 are located on three sides of the chip 201 electrically connected therewith and surround the chip 201.

In some examples, as shown in FIGS. 2 and 3A, the composite structure 20 further includes a connection wiring layer 204.

The connection wiring layer 204 is located on the surface of a side of the chip 201 close to the conductive layer 10. The connection wiring layer 204 includes connection wires 205 and the second pads 203 and the chip 201 is electrically connected with the second pads 203 via the connection wires 205.

The connection wires 205 in the second composite structure 22 extend onto the insulating layer 202 and are electrically connected with the second pads 203 on the insulating layer 202.

In some examples, as shown in FIG. 2, the plurality of composite structures 20 include a first composite structure 21 and at least one second composite structure 22. The one of the composite structures 20 that is closest to the conductive layer 10 is the first composite structure 21. The chip 201 in the first composite structure 21 is the target chip 201A.

It is appreciated that the second pads 203 in the first composite structure 21 can be provided at various locations, which may be selected depending on practical demands and is not limited in the present disclosure.

In some examples, in the first composite structure 21 as shown in FIG. 4, the second pads 203 are on the chip 201. Orthogonal projections of the second pads 203 on the conductive layer 10 are inside the range of orthogonal projection of the chip 201 on the conductive layer 10. That is to say, in the thickness direction of the first composite structure 21, the second pads 203 face directly the chip 201 electrically connected therewith. In the second composite structure 22, orthogonal projections of the second pads 203 on the conductive layer 10 do not overlap orthogonal projection of the chip 201 on the conductive layer 10. At this time, the second pads 203 of the first composite structure 21 and the second pads 203 of the second composite structures 203 are disposed at different locations. In the first composite structure 21, orthogonal projections of the conductive posts 30 electrically connected with the second pads 203 on the conductive layer 10 are also inside the range of orthogonal projection of the chip 201 on the conductive layer 10.

With the disposing manner, it is possible to make the conductive posts 30 and the second pads 203 in the first composite structure 21 face directly the chips 201 in the first composite structure 21, preventing the conductive posts and the second pads 203 from occupying spaces outside of the chips 201 separately, thereby facilitating miniaturization design and high integration design of the semiconductor device 1.

In some other examples, as shown in FIG. 2, the second pads 203 in the first composite structure 21 may be located on the insulating layer 202 and the respective conductive post 30 is located between the second pad 203 and the first pad 11 of the conductive layer 10. Therefore, it is possible to make the relative positions of the second pads 203 of the first composite structure 21 and the chip 201 same as the relative positions of the second pads 203 of the second composite structure 22 and the chip 201, which may simplify the manufacturing flow of composite structures 20 and optimize the manufacturing flow of the semiconductor device 1.

Hereinbelow, introduction will be presented for an example in which the second pads 203 in the first composite structure 21 are also located on the insulating layer 202.

There are various relative positions between the second pads 203 and the chip 201 electrically connected therewith, which are not limited in the present disclosure. For example, the second pads 203 of some of the composite structures 20 are located on the same side of the chip 201 electrically connected therewith. As another example, the second pads 203 of some of the composite structures 20 are located on the two opposite sides of the chip 201 electrically connected therewith.

Illustratively, as shown in FIG. 2, in the direction that is perpendicular to the plane in which the conductive layer 10 is located and away from the conductive layer 10, the distances between the conductive posts 30 connected with the second pads 203 on the same side of chip 201 in composite structure 20 and the chip of the first composite structure increase gradually.

For example, as shown in FIG. 2, the above-described “same side” is left side or right side in the second direction Y. In any two of the composite structures 20 other than the first composite structure 21, conductive posts 30 connected on the same side of chip of the composite structure 20 farther from the conductive layer 10 have larger distances from the target chip 201A.

In FIG. 2, L1 and L2 are distances between conductive posts 30 connected with the two composite structures 20 and the target chip 201A.

With the setting, it is possible to have relatively regular arrangements of the second pads 203 and the conductive posts 30 corresponding to the second pads 203, which facilitates simplifying the manufacturing flow of the semiconductor device 1. And in the thickness direction of the composite structures 20, it is possible to make the second pads 203 in different composite structures 20 to be offset, thereby avoiding short circuiting between the conductive posts 30 (other than conductive posts 30 electrically connected with the second pads 203 of the first composite structure 21) and connection wires 205 in other composite structures 20 when penetrating through the insulating layers 202, which would otherwise impact the function of the semiconductor device 1.

It is appreciated that sizes of chips 201 in different composite structures 20 may be the same or different, which is not limited herein. In case that sizes of chips 201 in various composite structures 20 are different, since the second pads 203 and the conductive posts 30 are disposed on the insulating layer 202 outside of the chips 201 in the present disclosure, relative positions of the composite structures 20 in the semiconductor device 1 may be selected flexibly and are not limited by sizes of chips 201.

For example, the composite structure 20 with chip 201 having the minimum size may serve as the first composite structure 21 in the semiconductor device 1, namely may be disposed at a position closest to the conductive layer 10. The composite structure 20 with chip 201 having the minimum size may also be disposed at other positions in the semiconductor device 1.

In some examples, as shown in FIG. 3A, the plurality of composite structures 20 further include a third composite structure 23 and a fourth composite structure 24 on a side of the first composite structure 21 away from the conductive layer 10. As compared to the fourth composite structure 24, the third composite structure 23 is closer to the conductive layer 10.

Illustratively, in the direction in which the fourth composite structure 24 points to the third composite structure 23, and in the thickness direction of the fourth composite structure 24, chip 201 in the fourth composite structure 24 face directly the chip 201 in the third composite structure 23 and chip 201 in the fourth composite structure 24 covers chip 201 in the third composite structure 23. That is, a line connecting the center of a chip 201 in the third composite structure 23 and the center of a chip 201 in the fourth composite structure 24 is approximately perpendicular to the plane in which the third composite structure 23 is located, and orthogonal projection of chip 201 in the third composite structure 23 on the conductive layer 10 is within ranges of the orthogonal projection of chip 201 in the fourth composite structure 24 on the conductive layer 10.

In some examples, as shown in FIG. 3A, distances between chip 201 in the third composite structure 23 and the second pads 203 electrically connected therewith are equal to the distances between chip 201 in the fourth composite structure 24 and the second pads 203 electrically connected therewith.

Therefore, it is easy to design the second pads 203 of the third composite structure 23 and the second pads 203 of the fourth composite structure 24, simplifying the manufacturing flow.

Of course, in some possible examples, as shown in FIG. 3B, distances between chip 201 in the third composite structure 23 and the second pads 203 electrically connected therewith are not equal to the distances between chip 201 in the fourth composite structure 24 and the second pads 203 electrically connected therewith.

In yet other examples, as shown in FIG. 2, in the thickness direction of the composite structures 20, chips 201 in composite structures 20 overlap each other. Orthogonal projections of chips 201 in composite structures 20 on the plane in which the conductive layer 10 is located are coincident with each other.

Illustratively, in the direction perpendicular to the plane in which the conductive layer 10 is located and in the direction in which the first composite structure 21 points to the second composite structures 22, the minimum distances between chip 201 in composite structure 20 and the second pads 203 electrically connected therewith increase gradually. Therefore, it is possible to make orthogonal projections of the second pads 203 on the conductive layer 10 not overlap and conductive posts 30 electrically connected with second pads 203 offset each other, avoiding short circuiting between conductive posts 30 and second pads 203 on the insulating layer while penetrating through the respective insulating layer.

In the examples, there may be various materials for the insulating layer 202 in the composite structure 20. For example, the insulating layer 202 may comprise an inorganic material or an organic material, which may be selected according to practical requirements.

In some examples, the insulating layer 202 includes an organic material. The organic material may be epoxy resin etc.

Therefore, it is possible to reduce the manufacturing process difficulty of the conductive posts 30 and reduce the manufacturing costs of the semiconductor device 1.

In some other examples, the insulating layer 202 includes an inorganic material. The inorganic material may be silicon oxide etc.

In some examples, as shown in FIGS. 2, 3A and 3B, the composite structure 20 further includes a dielectric layer 206 covering the chip 201 and the insulating layer 202.

The dielectric layer 206 covers the connection wiring layer 204 and protects the second pads 203 and the connection wires 205 in the connection wiring layer 204, preventing them from being eroded by water or oxygen. The conductive posts 30 penetrate through the insulating layer 202 and the dielectric layer 206 over the respective second pad 203 and are electrically connected with the second pads 203. For example, the dielectric layer 206 comprises an insulating material.

The material for the dielectric layer 206 and the material for the insulating layer 202 may be the same. For example, the material comprises epoxy resin or silicon oxide.

While manufacturing conductive posts, holes are generically drilled in the insulating layer and the dielectric layer with an etching process and then metal material is filled to form the conductive posts. Since materials for the dielectric layer and the insulating layer are the same, it is possible to apply the same etching process to etch the dielectric layer and the insulating layer at the same time, thereby facilitating simplifying the manufacturing process of conductive posts 30.

The material for the dielectric layer 206 and the material for the insulating layer 202 may also be different.

Some examples of the present disclosure further provide a chip package structure 2. As shown in FIG. 5, the chip package structure 2 includes: the semiconductor device 1 as described in any one of the above examples, and a packaging substrate 3 and a package housing 4. The packaging substrate 3 is attached to a side of the conductive layer 10 away from the composite structures 20. The package housing 4 is snap-fitted on the plurality of composite structures 20 and attached to the packaging substrate 3.

The packaging substrate 3 cooperates with the package housing 4 to protect the semiconductor device 1.

The beneficial effects that can be achieved by the chip package structure 2 provided in the example of the present disclosure can be inferred with reference to the beneficial effects of the manufacturing method of the semiconductor device 1 described above, and will not be described again herein.

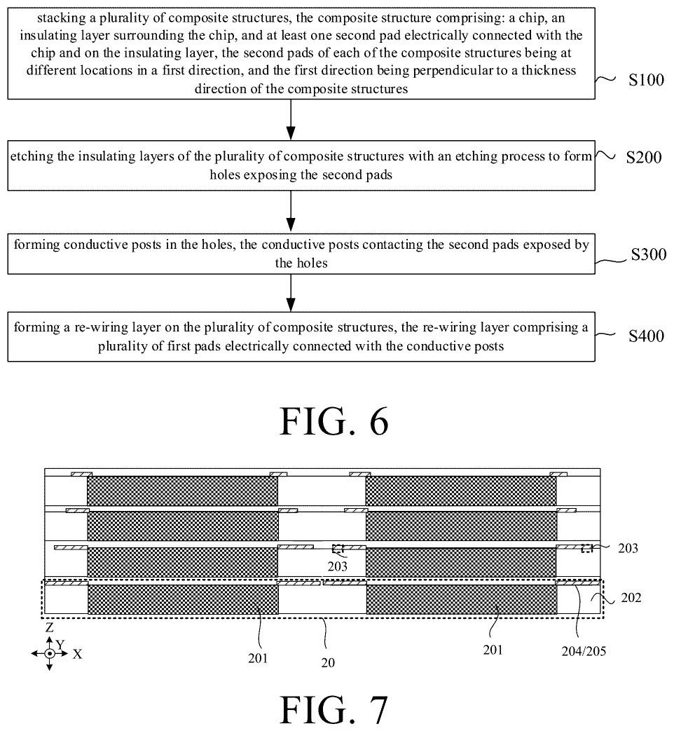

Some examples of the present disclosure further provide a manufacturing method of a semiconductor device for manufacturing the semiconductor device 1 in the above-described examples. As shown in FIG. 6, the manufacturing method includes S100-S400.

S100, as shown in FIG. 7, stacking a plurality of composite structures 20, a composite structure 20 comprising: a chip 201, an insulating layer 202 surrounding the chip 201 and at least one second pad 203 electrically connected with the chip 201, the second pad 203 being located on the insulating layer 202, the second pads 203 of each composite structure 20 being provided at different locations in a first direction X, the first direction X being perpendicular to the thickness direction of the composite structure 20.

In the thickness direction of the composite structure 20, chips 201 in the two adjacent composite structures 20 face each other directly.

The number of the chips 201 included in each composite structure 20 may be plurality. In this case, the insulating layer 202 is further filled between two adjacent chips 201.

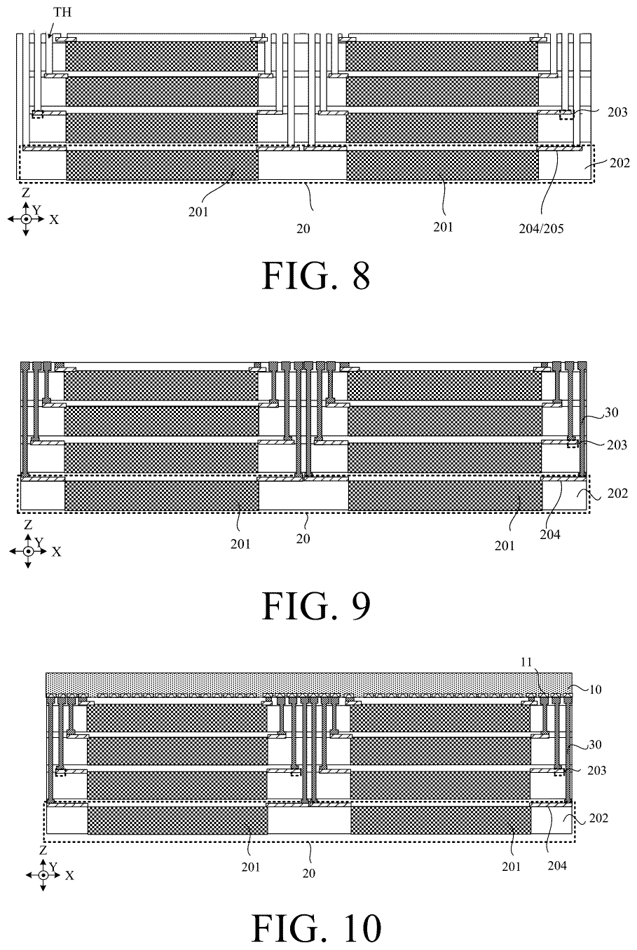

S200, as shown in FIG. 8, etching the insulating layers 202 of the plurality of composite structures 20 with an etching process to form holes TH exposing the second pads 203.

As compared to forming holes with other processes such as laser drilling process, etching process such as photolithography can make holes TH to have small and precise sizes, and the formed holes align well with respective second pad 203, thereby improving the yield of the semiconductor device 1.

S300, as shown in FIG. 9, forming conductive posts 30 in holes TH that contact the second pads 203 exposed by the holes.

Illustratively, the process for forming the conductive posts 30 in the holes may comprise vapor phase deposition and the conductive posts 30 may comprise a metal such as copper or tungsten.

Forming holes TH and conductive posts 30 with the manufacturing method allows the manufacturing method of holes TH and conductive posts 30 such as an etching process to be same as or compatible with the manufacturing method of some structures in the chips 201. Therefore, it is possible to manufacture the holes and the conductive posts with apparatuses applied in the process of manufacturing chips, avoiding designing again a set of manufacturing method and added manufacturing apparatuses for the semiconductor device, thereby simplifying the manufacturing flow of the semiconductor device 1, shortening the manufacturing period of the semiconductor device 1 and reducing the manufacturing costs of the semiconductor device 1.

S400, as shown in FIG. 10, forming a conductive layer 10 on the plurality of composite structures 20, the conductive layer 10 including a plurality of first pads 11 electrically connected with the conductive posts 30.

In examples of the present disclosure, a plurality of composite structures are stacked first, then the holes exposing the second pads 203 are formed with an etching process at corresponding locations on the insulating layers 202 of the stacked composite structures 20 and the conductive posts 30 are formed in the holes such that the conductive posts 30 are electrically connected with the first pads 11 and the second pads 203, thereby avoiding the manufacturing process and integration method in which the plurality of composite structures 20 are implemented by drilling inside the chips 201, without occupying spaces and areas inside the chips 201, which facilitates miniaturization design of the semiconductor device, can reduce manufacturing costs of the holes and the conductive posts 30, and reduce the difficulty of manufacturing process of the semiconductor device 1. It is also possible to make the manufacturing process of the semiconductor device 1 compatible with the manufacturing process of the chips 201, facilitating simplifying the manufacturing flow of the semiconductor device 1.

In some examples, forming the composite structures 20 includes S101-S105.

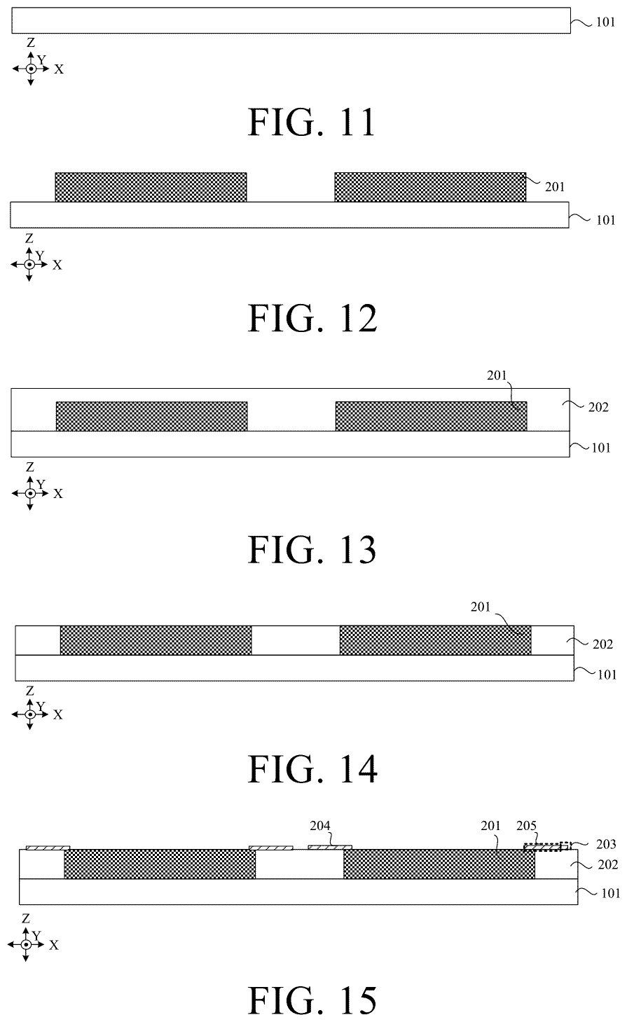

S101, as shown in FIG. 11, providing a carrier substrate 101.

For example, the carrier substrate 101 may comprise glass. The carrier substrate 101 may provide support for the composite structures 20.

S102, as shown in FIG. 12, disposing at least one chip 201 on the carrier substrate 101.

Illustratively, a plurality of chips 201 are fastened on the carrier substrate 101. The plurality of chips 201 are arranged at intervals with gaps between two adjacent chips 201. For example, the plurality of chips 201 are arranged in an array.

In case that a plurality of chips 201 are disposed on the carrier substrate 101, it is possible to allow each composite structure 20 to include a plurality of chips 201, and the plurality of chips in the composite structures may be separated in the thickness direction of the composite structure 20 after forming the conductive posts, thereby forming a plurality of semiconductor devices 1 at the same time, and shortening the manufacturing period of the semiconductor devices 1.

S103, as shown in FIG. 13, forming an insulating layer 202 on the carrier substrate 101, the insulating layer 202 surrounding the chip 201 and covering the chip 201.

For example, the process of forming the insulating layer 202 includes spin-coating etc.

The introduction in the above description may be referred to for the material of the insulating layer 202, which will not be described again herein.

For example, the material for the insulating layer 202 has a certain fluidity and is filled in the gaps between two adjacent chips 201 and around the chips 201. A surface of the insulating layer 202 away from the carrier substrate 101 is a roughly planar surface.

S104, as shown in FIG. 14, grinding the insulating layer 202 to expose the surface of a side of the chips 201 away from the carrier substrate 101.

Therefore, it facilitates electrically connecting the subsequently formed connection wires 205 with the chips 201.

For example, the insulating layer 202 may be grinded and thinned with chemical mechanical planarization (CMP) process or grinding process. After grinding the insulating layer 202, its surface away from the carrier substrate 101 is flush with the surface of the chip 201 away from the carrier substrate 101.

S105, as shown in FIG. 15, forming a connection wiring layer 204 on the surfaces of a side of the chips 201 away from the carrier substrate 101. The connection wiring layer 204 includes connection wires 205 and the second pads 203 and the chips 201 are electrically connected with the second pads 203 via the connection wires 205.

It is appreciated that there may be various arrangements for the connection wires 205, which may be selected according to practical requirements. In FIG. 15 of the present disclosure, the arrangement of the connection wires 205 is simplified as straight lines for convenient illustration, which does not limit all the connection wires 205 in examples of the present disclosure to straight lines.

For example, the connection wires 205 and the second pads 203 may be in the same layer and of the same material. “Same layer” refers to a layer structure formed by forming a film layer with the same film forming process for forming specific patterns and then subjecting the film layer to a one-time patterning process with the same mask. Depending on different specific patterns, the one-time patterning process may include various exposure, development or etching processes, while the specific patterns in the formed layer structure may be continuous or discontinuous, and these specific patterns may also be of different heights or have different thicknesses. Therefore, it is possible to implement patterning in one manufacturing process to form the connection wires 205 and the second pads 203 at the same time, thereby simplifying the manufacturing flow of the semiconductor device 1.

For example, as shown in FIG. 16, after forming the connection wiring layer 204, a dielectric layer 206 covering the connection wiring layer 205 and the second pads 203 is formed on a side of the connection wiring layer 204 away from the carrier substrate 101.

In some examples, forming the stacked composite structures 20 includes S110-S140.

S110, as shown in FIG. 17, attaching a temporary substrate 102 on a side of the i^{th} composite structure 20 away from the carrier substrate 101, wherein i is an integer and i≥2.

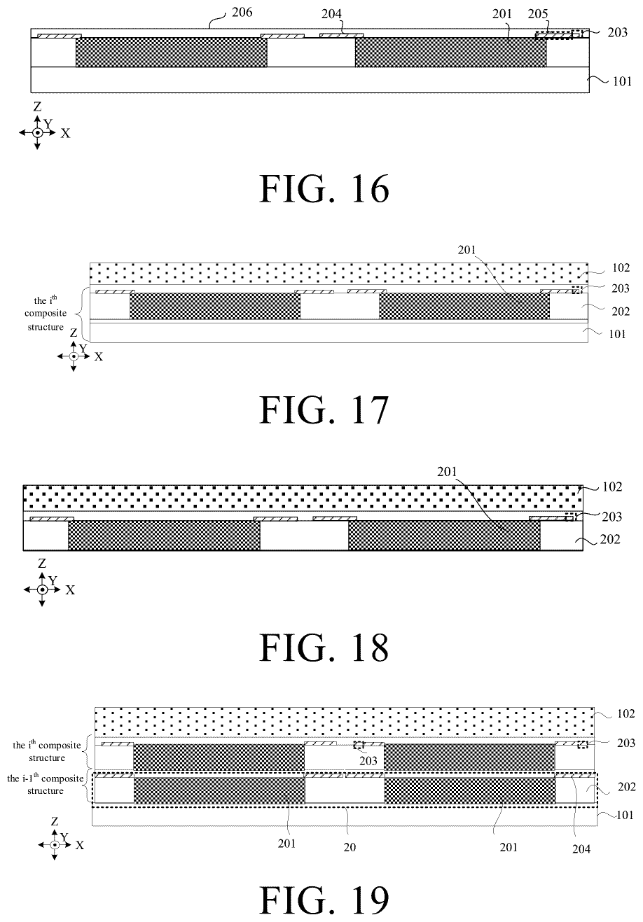

S120, as shown in FIG. 18, removing the carrier substrate 101.

S130, as shown in FIG. 19, attaching a surface of a side of the i^{th} composite structure 20 away from the temporary substrate 102 to a surface of a side of the i−1^{th} composite structure 20.

The surface of the side of the i−1^{th} composite structure 20 refers to the surface of the side of the i−1^{th} composite structure 20 away from the carrier substrate 101.

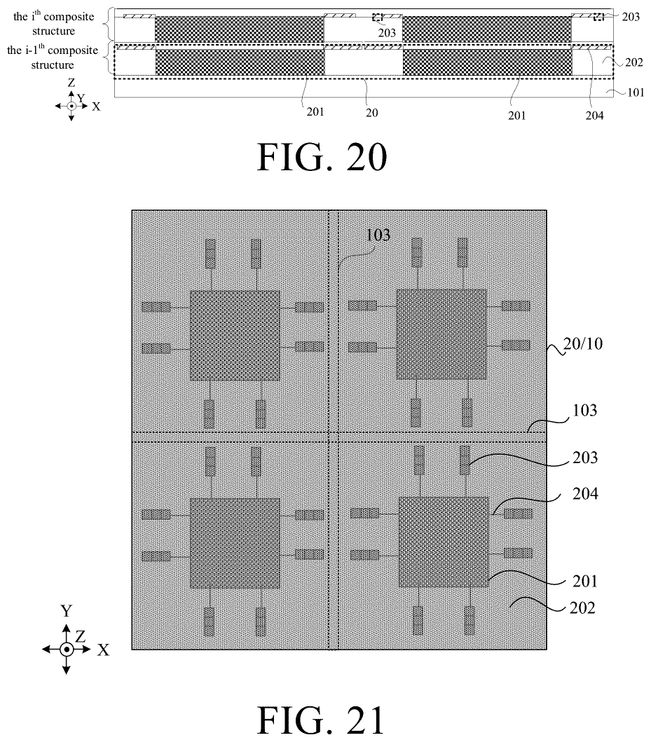

S140, as shown in FIG. 20, removing the temporary substrate 102.

For example, the number of the above-described composite structures 20 is n, wherein n is an integer, and n≥2, i≤n.

Considering an example in which n is 4, four stacked composite structures 20 are formed by successively taking i=2, i=3 and i=4. Specifically, taking i=2 first, the above-described S110-S140 are executed successively, then taking i=3, the above-described S110-S140 are executed successively, and then taking i=4, the above-described S110-S140 are executed successively, thereby stacking the four composite structures 20.

It is appreciated while stacking the plurality of composite structures 20, the carrier substrate for the first composite structure 20 has not been removed yet, a surface of a side of the second composite structure 20 away from the temporary substrate 102 is attached with a surface of a side of the first composite structure 20 away from the carrier substrate 101. A surface of a side of the third composite structure 20 away from the temporary substrate is attached with a surface of the second composite structure 20 away from the first composite structure 20. After forming the conductive layer 10, it is possible to remove the carrier substrate 101 of the first composite structure 20.

In some examples, as shown in FIG. 21, in case that the composite structure 20 includes a plurality of chips 201, the plurality of chips 201 are arranged at intervals; the conductive layer 10 has dicing lanes 103 that are located between two adjacent chips 201 in the direction perpendicular to the conductive layer 10 and separate the second pads 203 electrically connected with two adjacent chips 201. The plurality of dicing lanes 103 may be in the form of a grid and chips 201 are in the grid.

The manufacturing method also includes cutting the plurality of composite structures 20 along dicing lanes 103.

Therefore, each composite structure 20 in one semiconductor device 1 includes only one chip 201.

Some examples of the present disclosure further provide an electronic apparatus 5 including the chip package structure 2 in any one of the above-described examples.

Illustratively, the electronic apparatus may be any one of a mobile phone, a desktop computer, a tablet computer, a notebook computer, a server, an on-vehicle device, a wearable device such as a smart watch, a smart bracelet and a pair of smart glasses, a mobile power source, a game console, a digital multimedia player etc.

Examples of the present disclosure provide semiconductor devices and manufacturing methods thereof, as well as a chip package structure that implement miniaturization design and high integration design of semiconductor devices and chip package structures and may reduce the difficulty of manufacturing process and the manufacturing costs of the semiconductor devices and the chip package structures.

In order to achieve the above-described objects, examples of the present disclosure adopt the following technical solutions.

On the one hand, there is provided a semiconductor device including a conductive layer, a plurality of composite structures and a plurality of conductive posts. The conductive layer includes a plurality of first pads, the plurality of composite structures are located on the conductive layer and stacked in a direction perpendicular to a plane in which the conductive layer is located, the composite structure comprises: a chip, an insulating layer surrounding the chip, and at least one second pad electrically connected with the chip and on the insulating layer, the second pads of the plurality of composite structures are at different locations in a first direction, and the first direction is perpendicular to a thickness direction of the composite structures; and the plurality of conductive posts are located in the insulating layer of at least one of the composite structures, each of the conductive posts connects one of the second pads and one of the first pads.

In the semiconductor device provided in examples of the present disclosure, the composite structure comprises a second pad, a chip and an insulating layer, the second pad is disposed on the insulating layer surrounding the chip and electrically connected with the respective chip, the second pads of the plurality of composite structures are located at different locations in the first direction, and a plurality of conductive posts are disposed in the insulating layers of the composite structures, the first pads in the conductive layer are electrically connected with the second pads in the composite structures by the conductive posts, thereby avoiding applying the integration method in which the plurality of composite structures are implemented by drilling holes in the chips, without occupying space and areas in the chips, which facilitates miniaturization design of semiconductor devices, reduces the difficulty of manufacturing process of semiconductor devices and saves the manufacturing costs of semiconductor devices. Since the conductive posts are located in the insulating layer and the second pads are located on the insulating layer, the integration of composite structures is not limited by the area of chips in composite structures, which allows a high integration of semiconductor devices, a simpler integration of composite structures and makes the combination types of composite structures in the semiconductor device more flexible and drastically broaden the application scenario of the semiconductor device.

In some examples, the conductive posts extend in the direction perpendicular to the plane in which the conductive layer is located and are disposed parallel to each other.

In some examples, the composite structure of the plurality of composite structures closest to the conductive layer is a first composite structure, and in the direction perpendicular to the plane in which the conductive layer is located and away from the conductive layer, distances between the conductive posts connected with the second pads on same sides of the chips in the composite structures and the chip of the first composite structure increase gradually.

In some examples, the plurality of composite structures further comprise: at least one second composite structure on a side of the first composite structure away from the conductive layer, and the chips of the composite structures overlap in the thickness direction of the composite structures, and in the direction perpendicular to the plane in which the conductive layer is located and in a direction in which the first composite structure points to the second composite structure, minimum distances between the chips in the composite structures and the second pads electrically connected therewith increase gradually.

In some examples, the plurality of composite structures further comprise a third composite structure and a fourth composite structure on a side of the first composite structure away from the conductive layer, the third composite structure being closer to the conductive layer than the fourth composite structure; and in a direction in which the fourth composite structure points to the third composite structure and in the thickness direction of the fourth composite structure, the chip in the fourth composite structure faces directly the chip in the third composite structure, and the chip in the fourth composite structure covers the chip in the third composite structure; and a distance between the chip in the third composite structure and the second pad electrically connected therewith is equal to a distance between the chip in the fourth composite structure and the second pad electrically connected therewith.

In some examples, in the at least one of the composite structures, the number of the second pads electrically connected with the same chip is plurality; and distances between the chip and the plurality of second pads electrically connected therewith are equal.

In some examples, in the at least one of the composite structures, the number of the second pads electrically connected with the same chip is plurality; and a plurality of the second pads are located on at least two sides of the chip electrically connected therewith.

In some examples, the insulating layer comprises an organic material.

In some examples, the composite structure further comprises a connection wiring layer; the connection wiring layer is located on a surface of a side of the chip close to the conductive layer; and the connection wiring layer comprises connection wires and the second pads, and the chip is electrically connected with the second pads via the connection wires.

In some examples, the composite structure further comprises a dielectric layer covering the chip and the insulating layer; and the conductive posts penetrate through the insulating layer and the dielectric layer over the respective second pad and are electrically connected with the second pads.

On the other hand, there is provided a chip package structure comprising the semiconductor device of any one of the above-described examples, a packaging substrate and a package housing; wherein the packaging substrate is attached to a side of the conductive layer away from the composite structures in the semiconductor device, and the package housing is snap-fitted on the plurality of composite structures and attached to the packaging substrate.

In yet another aspect, there is provided a manufacturing method of a semiconductor device comprising: stacking a plurality of composite structures, the composite structure comprising: a chip, an insulating layer surrounding the chip, and at least one second pad electrically connected with the chip and on the insulating layer, the second pads of each of the composite structures being at different locations in a first direction, and the first direction being perpendicular to a thickness direction of the composite structures; and etching the insulating layers of the plurality of composite structures with an etching process to form holes exposing the second pads; forming conductive posts in the holes, the conductive posts contacting the second pads exposed by the holes; and forming a conductive layer on the plurality of composite structures, the conductive layer comprising a plurality of first pads electrically connected with the conductive posts.

In some examples, forming the composite structures comprises: providing a carrier substrate; disposing at least one chip on the carrier substrate; forming an insulating layer on the carrier substrate, the insulating layer surrounding and covering the chip; grinding the insulating layer to expose a surface of a side of the chip away from the carrier substrate; and forming a connection wiring layer on a surface of the side of the chip away from the carrier substrate, the connection wiring layer comprising connection wires and the second pads, and the chip is electrically connected with the second pads via the connection wires.

In some examples, said stacking the plurality of composite structures on the substrate comprises: attaching a temporary substrate on a side of the i^{th} composite structure away from the carrier substrate; wherein i is an integer and i≥2; removing the carrier substrate; attaching a surface on a side of the i^{th} composite structure with a surface of the i−1^{th} composite structure away from the substrate; and removing the temporary substrate.

In some examples, in case that the composite structure comprises a plurality of chips, the plurality of chips is disposed at intervals, and the conductive layer has dicing lanes that are located between two adjacent chips in a direction perpendicular to the conductive layer and separate the pads electrically connected with the two adjacent chips, and the manufacturing method further comprises: cutting the plurality of composite structures along the dicing lanes.

It is appreciated that the beneficial effects that can be achieved by the chip package structure and the manufacturing method of semiconductor device provided in the above-described examples of the present disclosure can be inferred with reference to the beneficial effects of the semiconductor device described above, and will not be described again herein.

What have been described above are only examples of the present disclosure, the scope of the present disclosure is not limited thereto. Variations and substitutions that easily occur to anyone having ordinary skill in the art in the technical scope disclosed by the present disclosure should be encompassed in the scope of the present disclosure. Therefore, the scope of the present disclosure should be determined by the scope of the claims.

What is claimed is:

1. A semiconductor device, comprising:
a conductive layer comprising a first pad;
a composite structure located on the conductive layer and stacked in a direction perpendicular to a plane in which the conductive layer is located, the composite structures comprising:
a chip,
an insulating layer surrounding the chip, and
a second pad connected with the chip and over the insulating layer, the second pad of the composite structure being at different locations in a first direction, and the first direction being perpendicular to a thickness direction of the composite structure; and
a conductive post located in the insulating of the composite structure, the conductive post connecting the first pad and the second pad.

2. The semiconductor device of claim 1, wherein a first conductive post extends in a direction perpendicular to the plane in which the conductive layer is located, and the first conductive post and a second conductive post are disposed parallel to each other.

3. The semiconductor device of claim 1, wherein the composite structure closest to the conductive layer is a first composite structure; and in the direction perpendicular to the plane in which the conductive layer is located and away from the conductive layer, a distance between a first conductive post and a second conductive post connected with the second pad on the same side of the chip in the composite structure and the chip of the first composite structure increases gradually.

4. The semiconductor device of claim 3, wherein the composite structure further comprises a second composite structure on a side of the first composite structure away from the conductive layer; and the chips of the composite structure overlaps in the thickness direction of the composite structure; and
in the direction perpendicular to the plane in which the conductive layer is located and in a direction in which the first composite structure points to the second composite structure, minimum distances between the chip in the composite structure and the second pad connected therewith increase gradually.

5. The semiconductor device of claim 3, wherein the composite structure further comprises a third composite structure and a fourth composite structure on a side of the first composite structure away from the conductive layer, the third composite structure being closer to the conductive layer than the fourth composite structure; and
in a direction in which the fourth composite structure points to the third composite structure and in the thickness direction of the fourth composite structure, the chip in the fourth composite structure faces directly the chip in the third composite structure, and the chip in the fourth composite structure covers the chip in the third composite structure; and a distance between the chip in the third composite structure and the second pad connected therewith is equal to a distance between the chip in the fourth composite structure and the second pad connected therewith.

6. The semiconductor device of claim 1, wherein in the at least one of the composite structures, the number of the second pads electrically connected with the same chip is plurality; and
distances between the chip and a number of second pads connected therewith are equal.

7. The semiconductor device of claim 1, wherein in the at least one of the composite structures, the number of the second pads electrically connected with the same chip is plurality; and
a plurality of the second pads are located on at least two sides of the chip electrically connected therewith.

8. The semiconductor device of claim 1, wherein the insulating layer comprises an organic material.

9. The semiconductor device of claim 1, wherein the composite structure further comprises a connection wiring layer;
the connection wiring layer is located on a surface of a side of the chip close to the conductive layer; and
the connection wiring layer comprises connection wires and the second pads, and the chip is electrically connected with the second pads via the connection wires.

10. The semiconductor device of claim 1, wherein the composite structure further comprises a dielectric layer covering the chip and the insulating layer; and
the conductive posts penetrate through the insulating layer and the dielectric layer over the respective second pads, and are electrically connected with the second pads.

11. A chip package structure, comprising:
a packaging substrate;
a package housing; and
a semiconductor device comprising:
a conductive layer comprising a first pad;
a composite structure located on the conductive layer and stacked in a direction perpendicular to a plane in which the conductive layer is located, the composite structure comprising: a chip, an insulating layer surrounding the chip, and a second pad electrically connected with the chip and over the insulating layer, the second pad of the composite structure being at different locations in a first direction, and the first direction being perpendicular to a thickness direction of the composite structure; and
a conductive post located in the insulating layer of the composite structure, the conductive post connecting the second pad and the first pad;
wherein the packaging substrate is attached to a side of the conductive layer away from the composite structure in the semiconductor device, and the package housing is snap-fitted on the composite structure and attached to the packaging substrate.

12. A manufacturing method of a semiconductor device comprising:
stacking a composite structure, the composite structure comprising: a chip, an insulating layer surrounding the chip, and a second pad connected with the chip and the insulating layer, a number of second pads of the composite structure being at different locations in a first direction, and the first direction being perpendicular to a thickness direction of the composite structure;
etching the insulating layer of the composite structure with an etching process to form holes exposing the second pads;
forming a conductive post in the holes, the conductive post contacting the second pad exposed by the holes; and
forming a conductive layer on the composite structure, the conductive layer comprising a first pad connected with the conductive post.

13. The manufacturing method of claim 12, wherein forming the composite structure comprises: providing a carrier substrate;
disposing a chip on the carrier substrate;
forming an insulating layer on the carrier substrate, the insulating layer surrounding and covering the chip;
grinding the insulating layer to expose a surface of a side of the chip away from the carrier substrate; and
forming a connection wiring layer on the surface of the side of the chip away from the carrier substrate, the connection wiring layer comprising connection wires and the second pad, and the chip is connected with the second pad via the connection wires.

14. The manufacturing method of claim 13, wherein stacking the composite structure comprises:
attaching a temporary substrate on a side of an i^{th} composite structure away from the carrier substrate, wherein i is an integer and i≥2;
removing the carrier substrate;
attaching a surface of the side of the i^{th} composite structure away from the temporary substrate with a surface of a side of an i−1^{th} composite structure; and
removing the temporary substrate.

15. The manufacturing method of claim 12, wherein the composite structure comprises a first chip and a second chip, the first chip and the second chip disposed at an interval, and the conductive layer has a dicing lane that are located between the first chip and the second chip in a direction perpendicular to the conductive layer and separate the second pad connected with the first chip and the second chip; and
the manufacturing method further comprises:
cutting the composite structure along the dicing lane.
